(19) United States
(12) Patent Application Publication
(10) Pub. No.: US 2011/0256371 A1
(43) Pub. Date: Oct. 20, 2011

(54) Hard Carbon Coating and Method of Forming The Same

(75) Inventor: Albir A. Layyous, Me'ilya (IL)

(73) Assignee: Iscar, Ltd., Tefen (IL)

(21) Appl. No.: 13/084,193

(22) Filed: Apr. 11, 2011

(30) Foreign Application Priority Data
Apr. 14, 2010 (IL) 205090

(51) Int. Cl. B32B 7/02; C23C 16/44; C23C 16/26; C23C 16/27; B32B 13/04; B32B 3/00

(52) U.S. Cl. 428/216; 428/446; 428/336; 427/249.7; 427/249.14; 427/575

(57) ABSTRACT

A coating for cutting tools or wear parts has at least one crystalline SiₓC_{1-x-y-z}N_{y}M_{z} layer formed by means of a PVD method and at least one hard carbon layer, which is diamond or DLC. Si and C are essential components of the SiₓC_{1-x-y-z}N_{y}M_{z} layer and M is one or more elements selected from among Ti, Zr, Hf, V, Nb, Ta, Cr, Mo, W, Y, B, Al and Ru (wherein 0.4≦x≦0.6, 0≦y≦0.1, and 0≦z≦0.2). The SiₓC_{1-x-y-z}N_{y}M_{z} layer has a half-value width of an SiC peak observed at 34° to 36° of diffraction angle when X-ray diffraction (XRD) is carried by using a CuKα ray is 3° or less. A method for forming the coating layer using PVD is carried out under certain temperature and substrate bias conditions.

### FIELD OF THE INVENTION

The present invention relates to a hard carbon coating that is used in applications which require excellent wear resistance, such as cutting tools and sliding members, and a method of forming the same.

### BACKGROUND OF THE INVENTION

Diamond, having exceptional properties of high hardness, high thermal conductivity, high compressive strength, wear resistance, high corrosion-resistance, and a low coefficient of friction, is a suitable coating for cutting tools particularly nonferrous metals such as Al alloys, graphite or ceramics. Cutting tools with cutting edges coated with a diamond layer or with a diamond like coating (DLC) are superior in strength, wear resistance and heat resistance, minimal adhesion and built-up edge generating fine workpiece surface finishes. Throughout the description and claims, a diamond layer is a layer of carbon in the sp3 phase, a DLC layer is a layer of carbon in both sp2 and sp3 phases with a sp3/sp2 ratio of at least 50%, and a hard carbon coating is a coating having at least one diamond layer or at least one DLC layer.

Hard metal cutting tools coated with a hard carbon coating usually fail due to insufficient strength of the interface between the hard carbon coating and the substrate. One contributing factor is the difference of the coefficient of thermal expansion (CTE). The CTE of cutting tools substrates such as cemented carbide, HSS, etc., is greater than the CTE of hard carbon coatings consequently the substrate shrinks more than the hard carbon coating when cooled from the deposition temperature, leading to high level of compressive residual stress of the hard carbon coating usually resulting in delamination of the coating.

Another cause of insufficient strength of the interface is that Fe and Co are both catalysts converting hard carbon into graphite so that when hard carbon is deposited on, for example, cemented carbide with a cobalt binder, a layer of graphite first grows followed by a hard carbon layer.

Diamond coatings are not chemically bonded to the substrate surface and the coating relies on a mechanical bond with the diamond film interlocking with WC grains on the tool surface. Producers of diamond coated tools usually etch the substrate's surface to expose grains of WC before coating and diamond films on cemented carbide tools are generally coarse-grained to provide the needed adhesion to the substrate. Coarse-grained (faceted) diamond, however, has disadvantages, including the inability to produce a very smooth workpiece surface finish. One solution to this problem is to etch away the Co binder from the surface layers of cemented carbide by various techniques, including acid etching. However, etching of Co binder reduces the interfacial surface strength of the cemented carbide article and the diamond coating and substantially reduces the strength of the hard metal substrate itself. Etching of Co from sharp edges will drastically reduce the sharp edge strength and thus greatly increase the likelihood of failure of the cutting tool during machining

Another known solution to the problem of adhesion of the hard coating to the substrate is to have a ceramic and/or metallic intermediate adhesion layer between the substrate and the hard carbon layer acting as diffusion barriers. For example JP 7026367 discloses one or more layers formed by a PVD method constituted of the carbides, nitrides and carbon nitrides of 4a, 5a and 6a group metals and Al₂O₃. JP 59170262 discloses a single layer of one kind of compound selected among the carbides, nitrides, carbonitrides, and oxycarbonitrides of the IVa, Va and VIa group metals in the periodic table, Si and B or a double layer of two or more kinds of compounds selected among said compounds. However, these ceramic interfacial layers do not form chemical bonds with hard carbon and therefore, do not provide good adhesion between the hard carbon coating and the substrate. Consequently, adhesion of hard carbon coatings to substrates remains a problem. Another example of an adhesion layer may be found in CA2150739 that discloses a process for coating a substrate with a polycrystalline diamond coating applied by CVD that are first coated with thin intermediate layers applied by CVD of which the diamond adherence layer is SiC or Si3N4.

Coatings incorporating CVD layers characterized by thermal cracks and residual tensile stress and an outermost PVD layer in a state of residual compressive stress are known, for example, from U.S. Pat. No. 5,143,488, U.S. Pat. No. 5,364,209, U.S. Pat. No. 5,250,367, and U.S. Pat. No. 5,266,388. The deposition of the PVD layer over the CVD layer(s) partially restores the loss in transverse rupture strength to the coating. These coatings are usually deposited over carbide enriched substrates and the layers of these coatings are typically selected from carbides, nitrides, carbonitrides, borides, boronitrides, oxycarbides, of Ti, Zr, and Hf, and the oxides, and oxynitrides of Al.

### SUMMARY OF THE INVENTION

In accordance with the present invention there is provided a coated member comprising a coating and a substrate, the coating comprising at least one intermediate layer and at least one hard carbon layer; wherein the hard carbon layer comprises diamond or DLC and forms the outermost layer of the coating;

the intermediate layer comprises a PVD-formed layer having a composition of SiₓC_{1-x-y-z}N_{y}M_{z} (where 0.4≦x≦0.6, 0≦y≦0.1, and 0≦z≦0.2), wherein Si and C are essential components and M is one or more elements selected from the group consisting of: Ti, Zr, Hf, V, Nb, Ta, Cr, Mo, W, Y, B, Al and Ru; and a half-value width of an SiC peak observed at 34° to 36° of diffraction angle when X-ray diffraction (XRD) is carried by using a CuKα ray is 3° or less.

In accordance with some embodiments, the coating comprises a laminated sequence comprising alternating layers of an intermediate layer and a hard carbon layer, the laminated sequence including a plurality of intermediate layers and a plurality of hard carbon layers.

Typically, all layers of the plurality of intermediate layers are from 10 nm to 10 μm; and all layers of the plurality of hard carbon layers are from 0.1 μm to 50 μm.

Optionally, at least two layers of the plurality of intermediate layers have different compositions; and/or at least two layers of the plurality of hard carbon layers have different compositions.

In accordance with some embodiments, the coating further comprises at least one first layer comprising one or more metals selected from the group consisting of Ti, Zr, Hf, V, Nb, Ta, Cr, Mo, W; and optionally further comprising one or more elements selected from the group consisting of: Si, Al, Y, B, N and C.

In accordance with some embodiments, the coating comprises a multi-layered structure comprising a plurality of first layers and a plurality of intermediate layers; wherein the outermost layer of the multi-layer structure is the intermediate layer.

Optionally, the multi-layered structure comprises at least two layers of the plurality of first layers of different compositions and/or at least two layers of the plurality of intermediate layers of different compositions.

Typically, all layers of the plurality of first layers of the multi-layered structure are from 5 nm to 10 μm.

Optionally, all layers of the plurality of first layers comprises two or more sublayers of different compositions.

Optionally, the coating comprises a laminated sequence comprising alternating layers of an intermediate layer and a hard carbon layer. The laminated sequence including a plurality of intermediate layers and a plurality of hard carbon; the laminated sequence is over the multi-layered structure. The outermost layer of the laminated sequence is one of said hard carbon layers and is also is the outermost layer of the coating.

Typically, the substrate is selected from the group consisting of: high speed steel, hard metals, oxide ceramics, carbide ceramics, boride ceramics, super abrasive materials, PcBN, PCD, and cermets or combinations thereof.

Typically, the member is selected from the group consisting of cutting tools, cutting inserts, jigs and friction members.

In another aspect of the invention, there is provided a method of making a coated member comprising a substrate and a coating. The method comprises the steps of:

(a) depositing, by means of a PVD method, an intermediate layer over the substrate the intermediate layer having a composition of SiₓC_{1-x-y-z}N_{y}M_{z} (where 0.4≦x≦0.6, 0≦y≦0.1, and 0≦z≦0.2), where M is one or more elements selected from the group consisting of: Ti, Zr, Hf, V, Nb, Ta, Cr, Mo, W, Y, B, Al and Ru, such that a half-value width of an SiC peak observed at 34° to 36° of diffraction angle when X-ray diffraction (XRD) is carried by using a CuKα ray is 3° or less:

wherein, during PVD deposition, the substrate being kept at a predetermined temperature between 400° C. and 800° C. and a predetermined bias voltage of −30 V to −300 V being applied to the substrate; and

(b) depositing a hard carbon layer on the intermediate layer, the hard carbon layer comprising diamond or DLC.

Optionally, the PVD method is a magnetron sputtering method.

Optionally, the method further comprises prior to carrying out step (a), (i) depositing a first layer over the substrate, wherein the first layer comprising one or more metals selected from the group consisting of Ti, Zr, Hf, V, Nb, Ta, Cr, Mo, W; wherein the thickness of the first layer is from 5 nm to 10 μm;

Optionally, the at least one first layer further comprises one or more elements selected from the group consisting of Si, Al, Y, B, N and C.

Optionally, the method further comprises after step (a) and before step (b), alternatingly depositing additional first layers and intermediate layers and/or after step (b), alternatingly depositing additional intermediate layers and hard carbon layers, wherein the final layer deposited is a hard carbon layer.

### BRIEF DESCRIPTION OF DRAWINGS

FIG. 1 is a schematic sectional view of a member coated with a coating according to a first embodiment of the invention,

FIG. 2a and FIG. 2b are schematic sectional views of members coated with coatings according to a second embodiment of the invention,

FIG. 3 is a schematic sectional view of a member coated with a coating according to a third embodiment of the invention, and

FIG. 4 is a schematic sectional view of a member coated with a coating according to a fourth embodiment of the invention.

### DETAILED DESCRIPTION OF THE INVENTION

The hard carbon coating of the invention may be deposited in any of the methods of hard carbon coating known in the art such as, by way of example hot filament CVD, combustion flame method, ECR (electron cyclotron resonance), or plasma assisted CVD (PCVD). The hard carbon coating may be ultrananocrystalline diamond, coarse grained diamond, or DLC.

Throughout the description and claims, the layer that is closest to the substrate is defined as an innermost layer and the layer that is farthest from the substrate is defined as an outermost layer.

FIG. 1 is a schematic sectional view of a member 1A according to a first embodiment of the invention. The member 1A has a substrate 2 coated with a coating 6A comprising an intermediate layer 5 and an outermost hard carbon layer 7.

Metallic materials such as iron-base alloys and hard metals, or cermets, ceramics, or super abrasives are suitably used as the substrate 2. In embodiments wherein the member 1A is used as a cutting tool, the hard metal is suitably used as the substrate 2.

The intermediate layer 5 has a composition of SiₓC_{1-x-y-z}N_{y}M_{z} (where 0.4≦x≦0.6, 0≦y≦0.1, and 0≦z≦0.2) having Si (silicon) and C (carbon) as its essential components and N (nitride) and an element M as its optional components. The element M is one or more elements selected from group consisting of Ti, Zr, Hf, V, Nb, Ta, Cr, Mo, W, Y, B, Al and Ru. The intermediate layer may have a compositional gradient with regard to the concentration of C, N, and/or M in the direction from the outer surface of the coating towards the substrate. The gradient being such that there is a difference between the average concentration of C, N, and/or M at the outermost portion of the intermediate layer and the average concentration of C, N, and/or M at the innermost portion of the intermediate layer.

It is noted that “crystalline” is those whose half-value width (FMHM: Full Width Half Maximum) of an SiC peak observed at 34° to 36° of diffraction angle 2θ when X-ray diffraction (XRD) is carried by using a CuKα ray is 3° or less and includes not only those substantially considered to be the SiC crystal but also those forming a compound structure including the SiC crystal and the amorphous SiC. Specifically, the peak observed at the 34° to 36° corresponds to a peak of a [111] face of a cubical crystal SiC.

The intermediate layer 5 is formed by using PVD methods described in WO 2009/150887. The intermediate layer 5 may be a thin layer of 10 nm or may be a thick layer of up to 10 μm.

The hard carbon layer 7 may be deposited according to CVD methods known in the art. The hard carbon layer 7 may be a thin layer of 0.1 μm, or may be a thick layer of up to 50 μm.

SiC (silicon carbide) has a hardness of at least 40 GPa and is excellent in oxidation resistance and wear resistance. Crystalline SiC film is formed essentially without cracks by controlling film forming conditions of a PVD method (disclosed in WO 2009/150887). This film has been found to be a good adhesion interface layer between the substrate or a coated substrate and a hard carbon layer or between two hard carbon layers. As explained above, the cobalt and/or nickel that is the binder in cemented carbide, is a catalyst converting hard carbon into graphite. XRD analysis shows a CoSi phase found in SiC layers deposited over cemented carbide substrates by CVD method, even when there are layers of TiN and/or TiCN between the substrate and the SiC layer. The temperature of the CVD method is between 800° C. and 1200° C. while the temperature of the PVD method is between 400° C. and 800° C. It has been now been found that the SiC film disclosed in WO 2009/150887 is greatly superior in its ability to serve as a diffusion barrier to elements present in the substrate, including cobalt, over known CVD SiC layers.

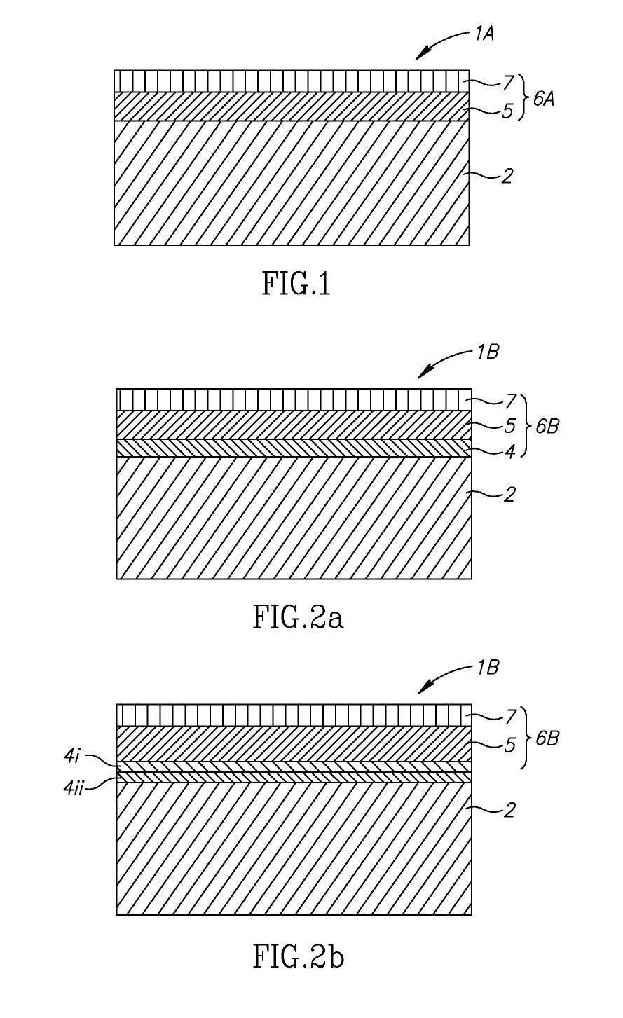

FIG. 2a and FIG. 2b are schematic sectional views of a member 1B according to a second embodiment of the invention. The substrate 2 of the member 1B is coated with a coating 6B. The coating 6B has three layers: an innermost first layer 4 formed on the surface of the substrate 2, an intermediate layer 5 provided on the first layer 4, and a hard carbon layer 7 formed on the intermediate layer 5.

The substrate 2 of the member 1B is the similar to the substrate 2 of member 1A described above. The intermediate layer 5 and hard carbon layer 7 of coating 6B are substantially the same with the intermediate layer 5 and hard carbon layer 7 of coating 6A described above.

The first layer 4 comprises one or more metals selected from the group of essential components consisting of Ti, Zr, Hf, V, Nb, Ta, Cr, Mo, and W and optionally further comprising and one or more elements selected from the group of elective components consisting of Si, Al, Y and B. In some embodiments of the invention the first layer 4 may be metallic or may be a mixture of essential and elective components. In other embodiments, the first layer 4 is ceramic and further comprises one or both nonmetal elements of N and C. The first layer 4 described above has an excellent adhesiveness with respect to the substrate 2. The intermediate layer 5 has excellent adhesiveness to the first layer 4. Accordingly, the coating 6B shows the excellent adhesiveness to the substrate 2 by providing the first layer 4 as the innermost layer of coating 6B. That is, the member 1B has improved adhesiveness between the substrate 2 and the hard carbon layer 7 to that of the aforementioned member 1A. Cutting tools, jigs and friction members to which the configuration of the member 1B is applied present an excellent durability.

The first layer 4 preferably has one or more of Ti and Cr as essential components and one or more elements selected from Y, Al and Si as elective components and in some embodiments is a nitride. The first layer 4 is preferably any one of Ti, Cr, TiN, CrN, TiC, TiAlN, CrAlN, TiCrAlN, TiCrAlSiN, TiAlSiN, and TiCrAlSiYN. Of these, Ti, CrN, TiAlN, CrAlN, TiCrAlN, TiCrAlSiN, TiAlSiN, and TiCrAlSiYN are especially in some applications for cutting tools. First layers 4 containing Al have improved oxidation resistance at high temperatures, such as those cutting tools attain while cutting resulting in improved cutting performance.

The first layer 4 is preferably at least 0.2 μm, more preferably at least 0.5 μm. As seen in FIG. 2b, in some embodiments, the first layer 4 has two or more sublayers 4i, 4ii, etc, whereas adjacent sublayers have different compositions. The sublayers may all have the same thickness or in some embodiments one or more of the sublayers may have unique thicknesses. The thickness of each of the sublayers of the first layer 4 is preferably at least 5 nm.

The first layer 4 may be formed by known methods such as an arc ion plating method or a CVD method. The intermediate layer 5 is formed on the first layer 4 by means of magnetron sputtering. It is preferable to use a film forming apparatus that can selectively perform the magnetron sputtering or the arc ion plating to the substrate mounted in its chamber.

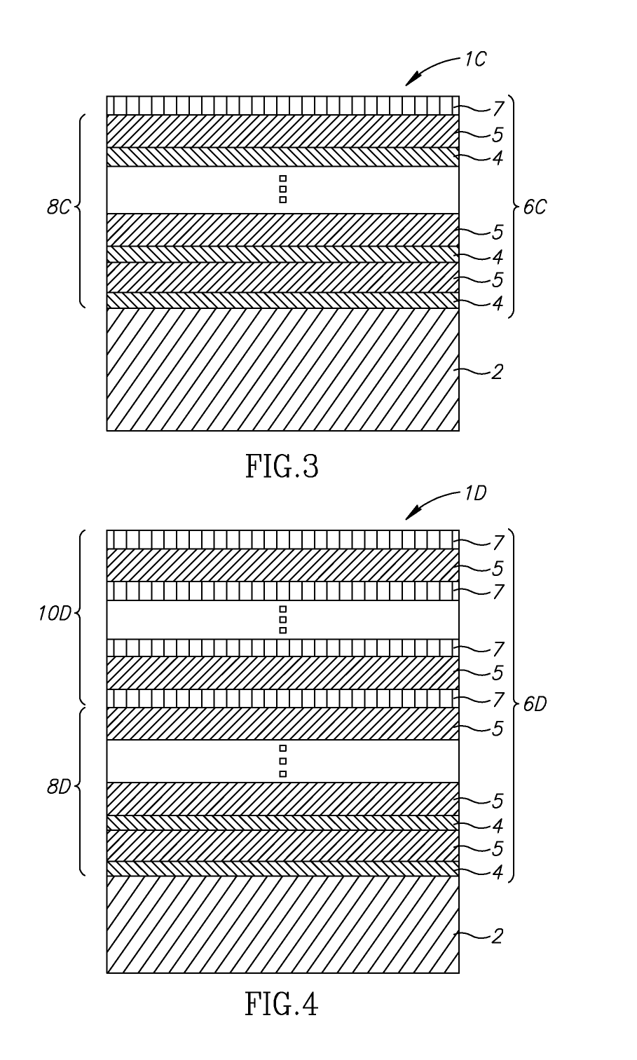

FIG. 3 is a schematic sectional view of a member 1C according to a third embodiment of the invention. Substrate 2 of the member 1C is coated by a coating 6C. The coating 6C has a multi-layered structure 8C comprising a plurality of first layers 4 and a plurality of intermediate layers 5 alternatingly deposited and the hard carbon layer 7 is deposited onto the multilayered structure. The multi-layered structure 8C has four or more layers. The outermost layer of the multi-layer structure 8C is the intermediate layer 5 which is adjacent to the hard carbon layer 7. The first layer 4 and the intermediate layer 5, and the hard carbon layer 7 constituting the hard film layer 8C are substantially the same as the first layer 4, the intermediate layer 5, and the hard carbon layer 7 described for members 1A and 1B described above. Because the coating 6C has a structure with numerous interfacial structures, the hardness thereof is enhanced and the wear resistance is improved. Therefore, cutting tools and sliding members made of the member 1C have an excellent durability.

The thickness of the each of the plurality of the first layers 4 and each of the plurality of intermediate layers 5 of the multi-layer structure 8C is preferably in the range of 5 nm to 10 μm, and more preferably 100 nm to 2 μm. In some embodiments, the composition of any of the plurality of the first layers 4 of the multi-layer structure 8C may be different from any other of the plurality of the first layers 4. Alternatively, any layer of the plurality of the first layer 4 may be of the same composition as at least one other layer of the plurality of the first layers 4. In some embodiments, the composition of any of the plurality of the intermediate layers 5 of the multi-layer structure 8C may be different from any other of the plurality of the intermediate layers 5. Alternatively, any layer of the plurality of the intermediate layers 5 may be of the same composition as at least one other layer of the plurality of intermediate layers 5. Preferably, the composition, the thickness and the number of layers of the multi-layer structure 8C is set so to reduce internal stress caused by the multiplicity of layers.

FIG. 4 is a schematic sectional view of a member 1D according to a fourth embodiment of the invention. The member 1D has a structure in which the surface of the substrate 2 is coated by a coating 6D. The coating 6D has a multi-layered structure 8D which is coated with a laminated sequence 10D. The multi-layered structure 8D in which a plurality of the first layers 4 and a plurality of the intermediate layers 5 are alternatingly deposited is similar to the multi-layered structure 8C described in coating 6C.

The laminated sequence 10D has alternating layers of a plurality of the hard carbon layers 7 and a plurality of the intermediate layers 5. The laminated sequence 10D has three or more layers. In some embodiments, the composition and/or thickness of any of the plurality of the intermediate layers 5 of the laminated sequence 10D may be different from any other of the plurality of intermediate layers 5. In the same way, in some embodiments, the composition and/or thickness of any of the plurality of the hard carbon layers 7 of the laminated sequence 10D may be different from any other of the plurality of hard carbon layers 7 of the laminated sequence 10D.

What is claimed is:

1. A coated member comprising a coating and a substrate, the coating comprising at least one intermediate layer and at least one hard carbon layer; wherein:
the hard carbon layer comprises diamond or DLC and forms the outermost layer of the coating;
the intermediate layer comprises a PVD-formed layer having a composition of SiₓC_{1-x-y-z}N_{y}M_{z} (where 0.4≦x≦0.6, 0≦y≦0.1, and 0≦z≦0.2), wherein Si and C are essential components and M is one or more elements selected from the group consisting of: Ti, Zr, Hf, V, Nb, Ta, Cr, Mo, W, Y, B, Al and Ru; and
a half-value width of an SiC peak observed at 34° to 36° of diffraction angle when X-ray diffraction (XRD) is carried by using a CuKα ray is 3° or less.

2. The coated member according to claim 1, wherein the coating comprises a laminated sequence comprising alternating layers of an intermediate layer and a hard carbon layer, the laminated sequence including a plurality of intermediate layers and a plurality of hard carbon layers.

3. The coated member according to claim 2, wherein:
all layers of the plurality of intermediate layers are from 10 nm to 10 μm; and
all layers of the plurality of hard carbon layers are from 0.1 μm to 50 μm.

4. The coated member according to claim 2, wherein:
at least two layers of the plurality of intermediate layers have different compositions; and/or
at least two layers of the plurality hard carbon layers have different compositions.

5. The coated member according to claim 1, wherein the coating further comprises at least one first layer comprising one or more metals selected from the group consisting of: Ti, Zr, Hf, V, Nb, Ta, Cr, Mo, W; wherein the innermost layer of the coating is the first layer and wherein the thickness of the first layer is from 5 nm to 10 μm.

6. The coated member according to claim 5, wherein the at least one first layer further comprises one or more elements selected from the group consisting of: Si, Al, Y, B, N, and C.

7. The coated member according to claim 5, wherein:
the coating comprises a multi-layered structure comprising alternating layers of a first layer and an intermediate layer, the multi-layered structure including a plurality of first layers and a plurality of intermediate layers; and
the outermost layer of the multi-layer structure is one of said intermediate layers.

8. The coated member according to claim 7, wherein:
at least two layers of the plurality of first layers have different compositions; and/or
at least two layers of the plurality of intermediate layers have different compositions.

9. The coated member according to claim 7, wherein all layers of the plurality of first layers are from 5 nm to 10 μm.

10. The coated member according to claim 7, wherein:
the coating comprises a laminated sequence comprising alternating layers of an intermediate layer and a hard carbon layer, the laminated sequence including a plurality of intermediate layers and a plurality of hard carbon;
the laminated sequence is over the multi-layered structure; and
the outermost layer of the laminated sequence is one of said hard carbon layers and is also is the outermost layer of the coating.

11. The coated member according to claim 7, wherein:
the innermost layer of the laminated sequence is one of said hard carbon layers.

12. The coated member according to claim 5, wherein one or more layers of the at least one first layer comprises two or more sublayers.

13. The coated member according to claim 1, wherein the member is selected from the group consisting of jigs, wear parts and friction members.

14. The coated member according to claim 1, wherein the member is a cutting tool.

15. A coated member comprising a coating and a substrate, the coating comprising:
a multi-layered structure over the substrate, the multi-layered structure comprising alternating layers of a first layer and an intermediate layer and including a plurality of first layers and a plurality of intermediate layers; and
a laminated structure atop the multi-layered structure, the laminated structure comprising alternating layers of the intermediate layer and a hard carbon layer and including a plurality of intermediate layers and a plurality of hard carbon layers; wherein:
each of the first layers comprises one or more metals selected from the group consisting of: Ti, Zr, Hf, V, Nb, Ta, Cr, Mo, W, wherein the thickness of each of the first layers is from 5 nm to 10 μm;
each of the intermediate layers comprises a PVD-formed layer having a composition of SiₓC_{1-x-y-z}N_{y}M_{z} (where 0.4≦x≦0.6, 0≦y≦0.1, and 0≦z≦0.2), wherein Si and C are essential components and M is one or more elements selected from the group consisting of: Ti, Zr, Hf, V, Nb, Ta, Cr, Mo, W, Y, B, Al and Ru; and wherein a half-value width of an SiC peak observed at 34° to 36° of diffraction angle when X-ray diffraction (XRD) is carried by using a CuKα ray is 3° or less;
each of the hard carbon layers comprises diamond or DLC;
the innermost layer of the coating is one of said first layers; and
the outermost layer of the coating is one of said hard carbon layers.

16. A method of making a coated member comprising a substrate and a coating, the method comprising the steps of:
(a) depositing, by means of a PVD method, an intermediate layer over the substrate, the intermediate layer having a composition of SiₓC_{1-x-y-z}N_{y}M_{z} (where 0.4≦x≦0.6, 0≦y≦0.1, and 0≦z≦0.2), where M is one or more elements selected from the group consisting of: Ti, Zr, Hf, V, Nb, Ta, Cr, Mo, W, Y, B, Al and Ru, such that a half-value width of an SiC peak observed at 34° to 36° of diffraction angle when X-ray diffraction (XRD) is carried by using a CuKα ray is 3° or less;
wherein, during PVD deposition, the substrate is kept at a predetermined temperature between 400° C. and 800° C. and a predetermined bias voltage of −30 V to −300 V is applied to the substrate; and
(b) depositing a hard carbon layer on the intermediate layer, the hard carbon layer comprising diamond or DLC.

17. The method according to claim 16, comprising depositing the intermediate layer by a PVD magnetron sputtering method.

18. The method according to claim 16, further comprising:
prior to carrying out step (a), depositing a first layer over the substrate, wherein the first layer comprises one or more metals selected from the group consisting of Ti, Zr, Hf, V, Nb, Ta, Cr, Mo, W; wherein the thickness of the first layer is from 5 nm to 10 μm.

19. The method according to claim 18, wherein the at least one first layer further comprises one or more elements selected from the group consisting of Si, Al, Y, B, N and C.

20. The method according to claim 18, further comprising:
after step (a) and before step (b), alternatingly depositing additional first layers and intermediate layers.

21. The method according to claim 20, further comprising:
after step (b), alternatingly depositing additional intermediate layers and hard carbon layers, wherein the final layer deposited is a hard carbon layer.
